(19) United States
(12) Patent Application Publication
(10) Pub. No.: US 2018/0135959 A1
(43) Pub. Date: May 17, 2018

(54) THIN FILM MEASURING APPARATUS AND THIN FILM MEASURING METHOD

(71) Applicant: Metal Industries Research & Development Centre, Kaohsiung (TW)

(72) Inventors: Chien-Chang Chen, Kaohsiung City (TW); Cheng-Chi Tai, Tainan City (TW)

(73) Assignee: Metal Industries Research & Development Centre, Kaohsiung (TW)

(21) Appl. No.: 15/635,214

(22) Filed: Jun. 28, 2017

(30) Foreign Application Priority Data
Nov. 17, 2016 (TW) 105137585

(51) Int. Cl. G01B 7/06; H05K 1/03; H05K 1/02; H05K 1/09; H05K 3/46

(52) U.S. Cl. CPC G01B 7/10; H05K 1/0326; H05K 1/0346; H05K 2201/0154; H05K 1/09; H05K 3/4644; H05K 3/467; H05K 1/028

(57) ABSTRACT

A thin film measuring apparatus includes a first sensing module, a second sensing module, and a processing device. The thin film measuring apparatus is configured to non-contact measure a multilayer thin film. The first sensing module and the second sensing module are respectively configured to generate alternating magnetic fields, and respectively sense magnetic field changes correspondingly generated by the multilayer thin film. The processing device has a parameter database. The processing device obtains a first impedance value and a second impedance value of the multilayer thin film according to sensing results of the first sensing module and the second sensing module. The processing device performs a thickness calculation operation to obtain a first thickness value and a second thickness value of the multilayer thin film according to the first impedance value, the second impedance value, and the parameter database. A thin film measuring method is also provided.

### CROSS-REFERENCE TO RELATED APPLICATION

This application claims the priority benefit of Taiwan application serial no. 105137585, filed on Nov. 17, 2016. The entirety of the above-mentioned patent application is hereby incorporated by reference herein and made a part of this specification.

### BACKGROUND OF THE INVENTION

### Field of the Invention

The invention relates to a measuring technique and more particularly relates to a thin film measuring apparatus and a thin film measuring method.

### Description of Related Art

In the field of measurement technology for metal thin films, most of the traditional thin film measuring apparatuses measure the thickness of metal thin films in a contact manner. Because such contact type measurement involves direct contact with the metal thin films, it may easily cause damage to the thin film body. For this reason, the traditional measurement technology usually extracts a portion of the sample and measures it in a static manner. In other words, with the traditional thin film measuring apparatus, it is not possible to measure the thickness of metal thin films online. Therefore, the result of measurement cannot be immediately passed on to the processing end for thin film thickness correction and adjustment. Moreover, the accuracy of the traditional thin film measuring apparatus only allows it to measure the thin film thickness of one single metal layer, and thus it cannot be used for measurement of a multilayer thin film structure. Hence, how to design a thin film measuring apparatus that is capable of measuring an um-level multilayer thin film structure and provides an online measurement function is an important issue in this field. In view of the above, several embodiments of the invention are provided as follows.

### SUMMARY OF THE INVENTION

The invention provides a thin film measuring apparatus, which is capable of measuring thicknesses of metal layers on two surfaces of a multilayer thin film by a first sensing module and a second sensing module in a non-contact manner and has an online measurement function.

A thin film measuring apparatus is adapted to measure a multilayer thin film in a non-contact manner. The thin film measuring apparatus includes a first sensing module, a second sensing module, and a processing device. The first sensing module and the second sensing module are respectively disposed at a side and another side of the multilayer thin film. The first sensing module and the second sensing module are adapted to respectively generate alternating magnetic fields, and respectively sense magnetic field changes correspondingly generated by the multilayer thin film. The processing device is coupled to the first sensing module and the second sensing module and includes a parameter database. The processing device obtains a first impedance value and a second impedance value of the multilayer thin film according to sensing results of the first sensing module and the second sensing module. The processing device executes a thickness calculation operation to obtain a first thickness value and a second thickness value of the multilayer thin film according to the first impedance value, the second impedance value, and the parameter database.

In an embodiment of the invention, the first sensing module and the second sensing module respectively include a sensing coil. The sensing coil is adapted to generate the alternating magnetic field, so that the multilayer thin film correspondingly generates an eddy current. The sensing coil is further adapted to sense the eddy current and output a sensing signal.

In an embodiment of the invention, the first sensing module and the second sensing module further respectively include a signal generation circuit, a controller, a driving circuit, and a signal processing circuit. The signal generation circuit is adapted to generate a sinusoidal signal. The controller is coupled to the signal generation circuit. The controller is adapted to control the signal generation circuit. The driving circuit is coupled to the sensing coil and the signal generation circuit. The driving circuit is adapted to drive the sensing coil according to the sinusoidal signal. The signal processing circuit is coupled to the sensing coil. The signal processing circuit is adapted to generate a signal processing result according to the sensing signal and the sinusoidal signal and output the signal processing result to the processing device via the controller. The processing device obtains a corresponding impedance value according to the signal processing result.

In an embodiment of the invention, the multilayer thin film has a structure formed by sequentially stacking a first metal layer, an insulating layer, and a second metal layer. The first metal layer has the first thickness value. The second metal layer has the second thickness value.

In an embodiment of the invention, the processing device measures a plurality of metal layers having different thicknesses by the first sensing module or the second sensing module, so that the processing device obtains a plurality of impedance values of the metal layers having different thicknesses to build the parameter database.

In an embodiment of the invention, the processing device further senses a plurality of multilayer thin film structures having different thicknesses by the first sensing module and the second sensing module, so as to obtain a plurality of impedance values of the multilayer thin film structures having different thicknesses to be inputted into the parameter database.

In an embodiment of the invention, a first adhesive layer is further disposed between the first metal layer and the insulating layer, and a second adhesive layer is further disposed between the second metal layer and the insulating layer. The first adhesive layer and the second adhesive layer are a metal material.

In an embodiment of the invention, the processing device further senses a plurality of adhesive layers having different thicknesses by the first sensing module or the second sensing module, so that the processing device obtains a plurality of impedance values of the adhesive layers having different thicknesses, and stores the plurality of impedance values into the parameter database.

A thin film measuring method is adapted to a thin film measuring apparatus. The thin film measuring apparatus is adapted to measure a multilayer thin film in a non-contact manner. The thin film measuring apparatus includes a first sensing module and a second sensing module. The thin film measuring method includes: respectively generating alternating magnetic fields by the first sensing module and the second sensing module to respectively sense magnetic field changes correspondingly generated by the multilayer thin film; obtaining a first impedance value and a second impedance value of the multilayer thin film according to sensing results of the first sensing module and the second sensing module; and executing a thickness calculation operation to obtain a first thickness value and a second thickness value of the multilayer thin film according to the first impedance value, the second impedance value, and a parameter database.

In an embodiment of the invention, the first sensing module and the second sensing module respectively include a sensing coil. The step of respectively generating the alternating magnetic fields by the first sensing module and the second sensing module to respectively sense the magnetic field changes correspondingly generated by the multilayer thin film includes: respectively sensing an eddy current correspondingly generated by the multilayer thin film by the sensing coils of the first sensing module and the second sensing module to respectively output a sensing signal.

In an embodiment of the invention, the step of respectively sensing the eddy current correspondingly generated by the multilayer thin film by the sensing coils of the first sensing module and the second sensing module to respectively output the sensing signal includes: respectively generating a sinusoidal signal; respectively driving the sensing coil according to the sinusoidal signal; respectively generating a signal processing result according to the sensing signal and the sinusoidal signal; and respectively obtaining a corresponding impedance value according to the signal processing result.

In an embodiment of the invention, the multilayer thin film has a structure formed by sequentially stacking a first metal layer, an insulating layer, and a second metal layer. The first metal layer has the first thickness value and the second metal layer has the second thickness value.

In an embodiment of the invention, thin film measuring method further includes: measuring a plurality of metal layers having different thicknesses by the first sensing module or the second sensing module to obtain a plurality of impedance values of the metal layers having different thicknesses; and storing the impedance values of the metal layers having different thicknesses into the parameter database.

In an embodiment of the invention, thin film measuring method further includes: sensing a plurality of multilayer thin films having different thicknesses by the first sensing module and the second sensing module to obtain a plurality of impedance values of the multilayer thin films having different thicknesses; and storing the impedance values of the multilayer thin films having different thicknesses into the parameter database.

In an embodiment of the invention, a first adhesive layer is further disposed between the first metal layer and the insulating layer, and a second adhesive layer is further disposed between the second metal layer and the insulating layer, and the first adhesive layer and the second adhesive layer are a metal material.

In an embodiment of the invention, thin film measuring method further includes: sensing a plurality of adhesive layers having different thicknesses by the first sensing module or the second sensing module to obtain a plurality of impedance values of the adhesive layers having different thicknesses; and storing the impedance values of the adhesive layers having different thicknesses into the parameter database.

Based on the above, according to the thin film measuring apparatus and the thin film measuring method disclosed in the embodiments of the invention, two impedance values of a multilayer thin film may be measured by two sensing modules in a non-contact manner, and instant calculation may be performed based on the parameter database to obtain the thicknesses of the metal layers on two surfaces of the multilayer thin film structure. Thus, the thin film measuring apparatus and the thin film measuring method disclosed in the embodiments of the invention may provide the function of online measurement.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a schematic diagram illustrating a thin film measuring apparatus according to an embodiment of the invention.

FIG. 2 is a schematic diagram illustrating a sensing module according to an embodiment of the invention.

FIG. 3 is a schematic diagram illustrating measurement of a multilayer thin film according to an embodiment of the invention.

FIG. 4 is a schematic diagram illustrating a thin film measuring method according to an embodiment of the invention.

### DESCRIPTION OF THE EMBODIMENTS

The following will describe some embodiments as examples of the invention. However, it should be noted that the invention is not limited to the disclosed embodiments. Moreover, some embodiments may be combined where appropriate. The term “couple” used throughout this specification (including the claims) may refer to any direct or indirect connection means. For example, if it is described that the first device is coupled to the second device, it should be understood that the first device may be directly connected to the second device or indirectly connected to the second device through other devices or certain connection means.

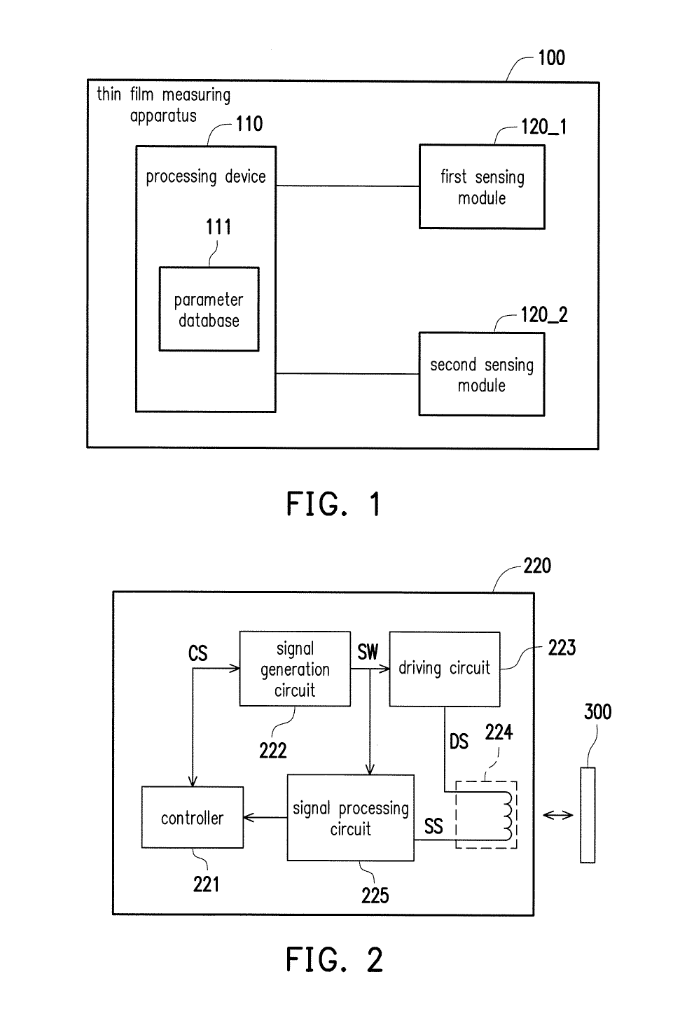

FIG. 1 is a schematic diagram illustrating a thin film measuring apparatus according to an embodiment of the invention. Referring to FIG. 1, a thin film measuring apparatus 100 includes a processing device 110, a first sensing module 120_1, and a second sensing module 120_2. The processing device 110 has a parameter database 111. In the present embodiment, the first sensing module 120_1 and the second sensing module 120_2 are respectively adapted to measure metal layer thicknesses of a multilayer thin film in a non-contact manner. In the present embodiment, the multilayer thin film is a flexible copper clad circuit (FCCL), for example, but the invention is not limited thereto. An object to be measured by the thin film measuring apparatus 100 of the present embodiment may be any multilayer thin film structure that uses a metal as a surface coating material.

More specifically, the first sensing module 120_1 and the second sensing module 120_2 may be disposed at one side and another one side of the multilayer thin film to be close to but not in contact with the multilayer thin film. First, the first sensing module 120_1 and the second sensing module 120_2 respectively generate alternating magnetic fields to correspondingly generate eddy currents at two positions on the one side and the another one side of the multilayer thin film. Then, the first sensing module 120_1 and the second sensing module 120_2 further respectively sense magnetic field changes correspondingly generated by the eddy currents at the two positions of the multilayer thin film for the processing device 110 to obtain a first impedance value and a second impedance value of the multilayer thin film according to sensing results of the first sensing module 120_1 and the second sensing module 120_2. Accordingly, the processing device 110 executes a thickness calculation operation according to the first impedance value, the second impedance value, and the parameter database 111, so as to obtain an actual first thickness value and an actual second thickness value of the multilayer thin film. In other words, because the thin film measuring apparatus 100 of the present embodiment uses a non-contact eddy current measuring technique, the thin film measuring apparatus 100 has the characteristic of instant measurement.

In the present embodiment, the thickness calculation operation refers to an operation that the processing device builds a two-dimensional matrix according to thickness parameters of various materials and corresponding impedance parameters in the parameter database 111, and performs calculation by mathematical interpolation according to the first impedance value and the second impedance value measured by the first sensing module 120_1 and the second sensing module 120_2, so as to obtain the corresponding first thickness value and second thickness value. The calculation performed by mathematical interpolation can be understood sufficiently based on the teaching, suggestion, and illustration relating to this field. Thus, details thereof are not repeated hereinafter.

In the present embodiment, the processing device 110 may include a single-core or multi-core central processing unit (CPU), a programmable microprocessor for general or special use, a digital signal processor (DSP), a programmable controller, an application specific integrated circuit (ASIC), a programmable logic device (PLD), other similar devices, or a combination of these devices for executing calculation of the impedance values and the thickness values in each of the embodiments of the invention. The processing device 110 may further include a memory component. The memory component is a random-access memory (RAM), a read-only memory (ROM), or a flash memory, for example, which is at least for storing the parameter database described in each embodiment of the invention, wherein the parameter database includes data of a plurality of thickness values and a plurality of corresponding impedance values.

FIG. 2 is a schematic diagram illustrating a sensing module according to an embodiment of the invention. Referring to FIG. 2, a sensing module 220 may be the first sensing module and the second sensing module described in each of the embodiments of the invention, for example. In the present embodiment, the sensing module 220 includes a controller 221, a signal generation circuit 222, a driving circuit 223, a sensing coil 224, and a signal processing circuit 225. In the present embodiment, the controller 221 outputs a control signal CS to the signal generation circuit 222 to control the signal generation circuit 222 to generate a sinusoidal signal SW. The driving circuit 223 generates a driving signal DS to the sensing coil 224 according to the sinusoidal signal SW, so that the sensing coil 224 generates an alternating magnetic field. Further, a multilayer thin film 300 may generate a magnetic field change corresponding to the alternating magnetic field. Then, the sensing coil 224 senses the magnetic field change correspondingly generated by the multilayer thin film 300 to output a sensing signal to the signal processing circuit 225. In the present embodiment, the signal processing circuit 225 takes the sinusoidal signal SW as a reference signal and performs a signal processing operation according to the sinusoidal signal SW and the sensing signal SS to obtain a signal processing result. Thereafter, the signal processing circuit 225 provides the signal processing result to the processing device via the controller 221. That is, In the present embodiment, the signal processing circuit 225 may compare signal waveforms before and after the sensing to obtain an influence of the thin film impedance on the sensing signal SS, and further obtain the impedance value through a relationship between the electromagnetic signal and the impedance value. For example, the signal processing circuit 225 may calculate the corresponding impedance values according to the sinusoidal signal SW and the sensing signal SS, or calculate an impedance difference before and after the sensing. Nevertheless, the invention is not limited thereto.

In addition, the sensing coil 224 of the present embodiment is, for example, a high frequency probe coil for generating a high frequency alternating magnetic field at MHz level, wherein an operation frequency thereof may be 1 MHz, for example. Therefore, the sensing module 220 may be used to measure a multilayer thin film structure having a thin film thickness of 1 um to 20 um, but the invention is not limited thereto. In one embodiment, the operation frequency of the sensing coil 224 may be determined by the type of the thickness of the multilayer thin film.

FIG. 3 is a schematic diagram illustrating measurement of a multilayer thin film according to an embodiment of the invention. Referring to FIG. 3, a thin film measuring apparatus 400 includes a processing device 410, a first sensing module 420_1, and a second sensing module 420_2. The processing device 410 is coupled to the first sensing module 420_1 and the second sensing module 420_2. In the present embodiment, the first sensing module 420_1 and the second sensing module 420_2 are respectively disposed at the one side and the another one side of a multilayer thin film 500. The first sensing module 420_1 and the second sensing module 420_2 are respectively adapted to generate alternating magnetic fields, and respectively sense magnetic field changes correspondingly generated by the multilayer thin film 500. Moreover, the processing device 410 of the present embodiment may have a memory device and further store a parameter database therein, wherein details of the technical features of the parameter database can be understood from the teaching, suggestion, and description of implementation in the embodiment of FIG. 1, and thus are not repeated hereinafter.

In the present embodiment, the multilayer thin film 500 has a structure that is formed by sequentially stacking a first metal layer 510, a first adhesive layer 520, an insulating layer 530, a second adhesive layer 540, and a second metal layer 550, wherein the first metal layer 510 has a first thickness value and the second metal layer 550 has a second thickness value. For example, the multilayer thin film 500 of the present embodiment may be a flexible copper clad circuit (FCCL). The first metal layer 510 and the second metal layer 550 may be copper (Cu). The first adhesive layer 520 and the second adhesive layer 540 may be nickel (Ni). The insulating layer 530 may be a polyimide (PI) insulating substrate. Nevertheless, the invention is not limited thereto. The type of the material of each layer of the multilayer thin film 500 may be determined by the type of the thin film.

In the present embodiment, the thin film measuring apparatus 400 first builds a parameter database relating to single material layers and multilayer thin film structures, and then performs a measurement operation for the multilayer thin film 500. More specifically, the thin film measuring apparatus 400 may measure a plurality of single metal layer thin films having different thicknesses in advance by the first sensing module 420_1 or the second sensing module 420_2 for the processing device 410 to obtain a plurality of impedance values of the single metal layers having different thicknesses. Accordingly, the processing device 410 may build a parameter database including the impedance values of the single metal layers and the corresponding thickness values. Then, In the present embodiment, the thin film measuring apparatus 400 may measure a plurality of single adhesive layer thin films having different thicknesses in advance by the first sensing module 420_1 or the second sensing module 420_2 for the processing device 410 to obtain a plurality of impedance values of the single adhesive layers having different thicknesses. Accordingly, the processing device 410 may input the impedance values of the single adhesive layers and the corresponding thickness values to the parameter database. Thereafter, the thin film measuring apparatus 400 may measure a plurality of multilayer thin film structures having different thicknesses in advance by the first sensing module 420_1 and the second sensing module 420_2 for the processing device 410 to obtain a plurality of impedance values of the multilayer thin film structures having different thicknesses. Accordingly, the processing device 410 may input the impedance values of the multilayer thin film structures and the corresponding thickness values to the parameter database, and further simulate two-dimensional matrices relating to multiple thickness values and multiple impedance values.

In the present embodiment, after building the parameter database of the processing device 410 is completed, the user may operate the thin film measuring apparatus 400 to measure the multilayer thin film 500. The processing device 410 may obtain a first impedance value and a second impedance value of the multilayer thin film according to sensing results of the first sensing module 420_1 and the second sensing module 420_2. In the present embodiment, when the processing device 410 executes the thickness calculation operation, the processing device 410 may first eliminate the influence of electromagnetic sensing that the metal layer at the other end has on the first sensing module and the second sensing module, and then calculate the actual impedance values and actual thickness values corresponding to the first metal layer 510 and the second metal layer 550 by interpolation according to the simulated two-dimensional matrices.

In addition, the structural features of the multilayer thin film 500 are not limited to the disclosure of FIG. 3. In one embodiment, the multilayer thin film 500 may have a three-layer thin film structure, such as an adhesive-free copper foil circuit. The multilayer thin film 500 may include the first metal layer 510, the insulating layer 530, and the second metal layer 550, but include no adhesive layer. In other words, in order to build the parameter database, the thin film measuring apparatus 400 only needs to measure multiple single metal layer thin films having different thicknesses and multiple multilayer thin film structures having different thicknesses in advance. That is to say, the thin film measuring apparatus 400 may build the parameter database according to different thin film types for the processing device 410 to execute the operation, as described above, and calculate the actual impedance values and the actual thickness values corresponding to the first metal layer 510 and the second metal layer 550 by interpolation according to the simulated two-dimensional matrices.

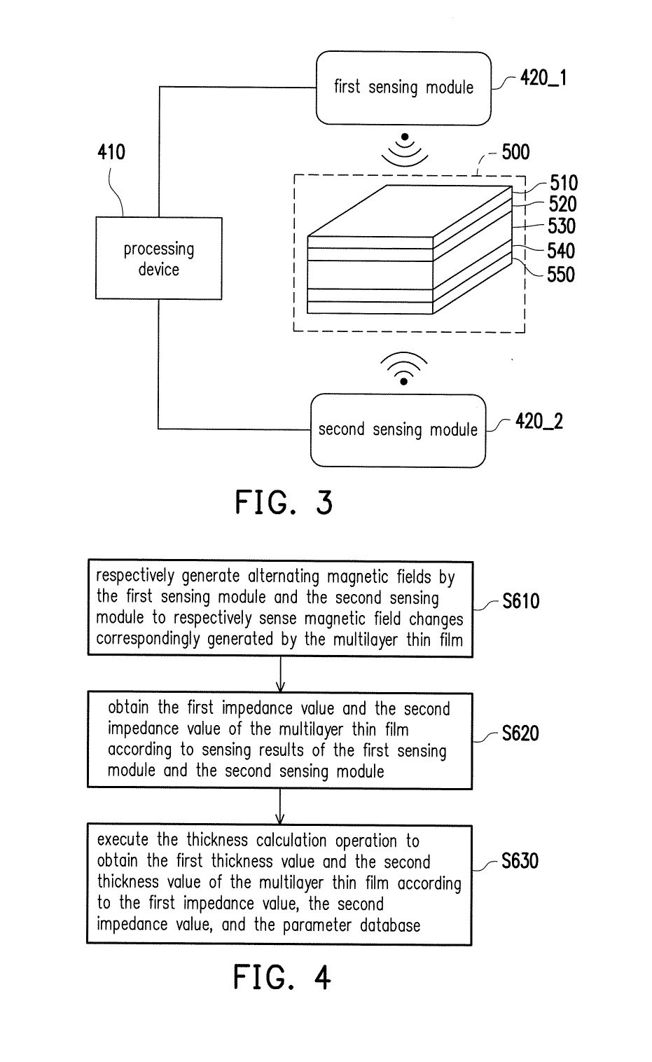

FIG. 4 is a flowchart illustrating a thin film measuring method according to an embodiment of the invention. Referring to FIG. 3 and FIG. 4, the method of the present embodiment is at least applicable to the thin film measuring apparatus 400 shown in FIG. 3. In the present embodiment, the thin film measuring apparatus 400 is used to measure the multilayer thin film 500 in a non-contact manner. The thin film measuring apparatus 400 includes the first sensing module 420_1 and the second sensing module 420_2. In Step S610, the thin film measuring apparatus 400 respectively generates alternating magnetic fields by the first sensing module 420_1 and the second sensing module 420_2 to respectively sense magnetic field changes correspondingly generated by the multilayer thin film 500. In Step S620, the thin film measuring apparatus 400 obtains the first impedance value and the second impedance value of the multilayer thin film 500 according to sensing results of the first sensing module 420_1 and the second sensing module 420_2. In Step S630, the thin film measuring apparatus 400 executes the thickness calculation operation to obtain the first thickness value of the first metal layer 510 and the second thickness value of the second metal layer 550 according to the first impedance value, the second impedance value, and the parameter database stored in the processing device 410. Accordingly, the thin film measuring method of the present embodiment may be applied for an online measurement operation and for measuring a multilayer thin film structure to obtain the thicknesses of coating materials (metal layers) on two surfaces of the multilayer thin film.

Moreover, the thin film measuring method of the present embodiment can be understood sufficiently from the teaching, suggestion, and illustration of the embodiments of FIG. 1 to FIG. 3. Thus, details thereof are not repeated hereinafter.

In conclusion, according to the thin film measuring apparatus and the thin film measuring method disclosed in the exemplary embodiments of the invention, non-contact measurement may be performed on the multilayer thin film that has both surfaces plated with metal layers by the first sensing module and the second sensing module. The thin film measuring apparatus may obtain the impedance values of multiple single metal layers including different materials and having different thicknesses in advance to build the parameter database in advance. Thus, when measuring the multilayer thin film by the first sensing module and the second sensing module, the thin film measuring apparatus may instantly calculate the first impedance value measured by the first sensing module and the second impedance value measured by the second sensing module to obtain the actual first thickness value and second thickness value of the metal layers on two sides of the multilayer thin film. Accordingly, the thin film measuring apparatus and the thin film measuring method of the present embodiment may provide a function for instantly measuring the thicknesses of the metal layers of the multilayer thin film online.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

What is claimed is:

1. A thin film measuring apparatus adapted to measure a multilayer thin film in a non-contact manner, the thin film measuring apparatus comprising:
a first sensing module and a second sensing module, respectively disposed at a side and another side of the multilayer thin film to respectively generate alternating magnetic fields, and respectively sense magnetic field changes correspondingly generated by the multilayer thin film; and
a processing device, coupled to the first sensing module and the second sensing module, and comprising a parameter database,
wherein the processing device obtains a first impedance value and a second impedance value of the multilayer thin film according to sensing results of the first sensing module and the second sensing module, and executes a thickness calculation operation to obtain a first thickness value and a second thickness value of the multilayer thin film according to the first impedance value, the second impedance value, and the parameter database.

2. The thin film measuring apparatus according to claim 1, wherein the first sensing module and the second sensing module respectively comprise:
a sensing coil, adapted to generate the alternating magnetic field, so that the multilayer thin film correspondingly generates an eddy current,
wherein the sensing coil is further adapted to sense the eddy current and output a sensing signal.

3. The thin film measuring apparatus according to claim 2, wherein the first sensing module and the second sensing module further respectively comprise:
a signal generation circuit, adapted to generate a sinusoidal signal;
a controller, coupled to the signal generation circuit, and adapted to control the signal generation circuit;
a driving circuit, coupled to the sensing coil and the signal generation circuit, and adapted to drive the sensing coil according to the sinusoidal signal; and
a signal processing circuit, coupled to the sensing coil, and adapted to generate a signal processing result according to the sensing signal and the sinusoidal signal, and output the signal processing result to the processing device via the controller,
wherein the processing device obtains a corresponding impedance value according to the signal processing result.

4. The thin film measuring apparatus according to claim 1, wherein the multilayer thin film has a structure formed by sequentially stacking a first metal layer, an insulating layer, and a second metal layer, wherein the first metal layer has the first thickness value, and the second metal layer has the second thickness value.

5. The thin film measuring apparatus according to claim 4, wherein the processing device measures a plurality of metal layers having different thicknesses by the first sensing module or the second sensing module, so that the processing device obtains a plurality of impedance values of the metal layers having different thicknesses to build the parameter database.

6. The thin film measuring apparatus according to claim 5, wherein the processing device further senses a plurality of multilayer thin film structures having different thicknesses by the first sensing module and the second sensing module, so that the processing device obtains a plurality of impedance values of the multilayer thin film structures having different thicknesses, and stores the plurality of impedance values into the parameter database.

7. The thin film measuring apparatus according to claim 4, wherein a first adhesive layer is further disposed between the first metal layer and the insulating layer, and a second adhesive layer is further disposed between the second metal layer and the insulating layer, wherein the first adhesive layer and the second adhesive layer are a metal material.

8. The thin film measuring apparatus according to claim 7, wherein the processing device further senses a plurality of adhesive layers having different thicknesses by the first sensing module or the second sensing module, so that the processing device obtains a plurality of impedance values of the adhesive layers having different thicknesses, and stores the plurality of impedance values into the parameter database.

9. A thin film measuring method, adapted to a thin film measuring apparatus, the thin film measuring apparatus is adapted to measure a multilayer thin film in a non-contact manner, and the thin film measuring apparatus comprises a first sensing module and a second sensing module, wherein the thin film measuring method comprising:
respectively generating alternating magnetic fields by the first sensing module and the second sensing module to respectively sense magnetic field changes correspondingly generated by the multilayer thin film;
obtaining a first impedance value and a second impedance value of the multilayer thin film according to sensing results of the first sensing module and the second sensing module; and
executing a thickness calculation operation to obtain a first thickness value and a second thickness value of the multilayer thin film according to the first impedance value, the second impedance value, and a parameter database.

10. The thin film measuring method according to claim 9, wherein the first sensing module and the second sensing module respectively comprise a sensing coil, and respectively generating the alternating magnetic fields by the first sensing module and the second sensing module to respectively sense the magnetic field changes correspondingly generated by the multilayer thin film comprises:
respectively sensing an eddy current correspondingly generated by the multilayer thin film by the sensing coils of the first sensing module and the second sensing module to respectively output a sensing signal.

11. The thin film measuring method according to claim 10, wherein respectively sensing the eddy current correspondingly generated by the multilayer thin film by the sensing coils of the first sensing module and the second sensing module to respectively output the sensing signal comprises:
respectively generating a sinusoidal signal;
respectively driving the sensing coil according to the sinusoidal signal;
respectively generating a signal processing result according to the sensing signal and the sinusoidal signal; and
respectively obtaining a corresponding impedance value according to the signal processing result.

12. The thin film measuring method according to claim 9, wherein the multilayer thin film has a structure formed by sequentially stacking a first metal layer, an insulating layer, and a second metal layer, wherein the first metal layer has the first thickness value and the second metal layer has the second thickness value.

13. The thin film measuring method according to claim 12, further comprising:
measuring a plurality of metal layers having different thicknesses by the first sensing module or the second sensing module to obtain a plurality of impedance values of the metal layers having different thicknesses; and
storing the impedance values of the metal layers having different thicknesses into the parameter database.

14. The thin film measuring method according to claim 13, further comprising:
sensing a plurality of multilayer thin films having different thicknesses by the first sensing module and the second sensing module to obtain a plurality of impedance values of the multilayer thin films having different thicknesses; and
storing the impedance values of the multilayer thin films having different thicknesses into the parameter database.

15. The thin film measuring method according to claim 12, wherein a first adhesive layer is further disposed between the first metal layer and the insulating layer, and a second adhesive layer is further disposed between the second metal layer and the insulating layer, wherein the first adhesive layer and the second adhesive layer are a metal material.

16. The thin film measuring method according to claim 15, further comprising:
sensing a plurality of adhesive layers having different thicknesses by the first sensing module or the second sensing module to obtain a plurality of impedance values of the adhesive layers having different thicknesses; and
storing the impedance values of the adhesive layers having different thicknesses into the parameter database.
